(19) United States
(12) Patent Application Publication
(10) Pub. No.: US 2015/0346258 A1
(43) Pub. Date: Dec. 3, 2015

(54) Method and device for monitoring a protective ground connection

(71) Applicant: Bender GmbH & Co. KG, Gruenberg (DE)

(72) Inventor: Bernd Haeuslein, Nuernberg (DE)

(21) Appl. No.: 14/719,441

(22) Filed: May 22, 2015

(30) Foreign Application Priority Data
May 30, 2014 (DE) 10 2014 210 290.1

(51) Int. Cl. G01R 31/02

(52) U.S. Cl. CPC G01R 31/025

(57) ABSTRACT

A method and a device are for monitoring a protective ground of an electrical feeder using a monitoring conductor, the feeder extending between a feeding point having a grounding connection and a load-side connection, and a test current injected at the feeding point between the monitoring conductor and the grounding connection.

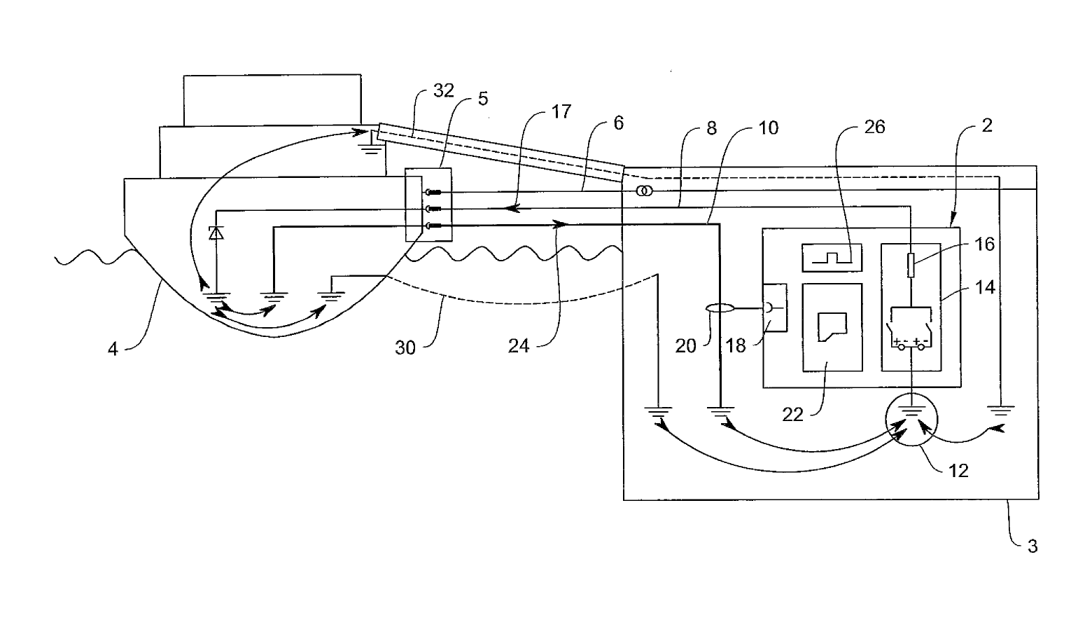

The injected test current has a characteristic temporal progression distinguishable from the currents running on the protective ground, the protective ground current measured at the feeding side and the measured protective ground current evaluated to detect an interruption of the protective ground.

The injected test current, which is generated by the active measuring method, has a progression distinguishable from the other currents running on the protective ground. On the other hand, a current measurement takes place selectively on the feeding side in the protective ground to be monitored in conjunction with an evaluation of the measured protective ground current.

This application claims the benefit of German Patent Application No. 10 2014 210 290.1, filed May 30, 2014, the disclosure of which is incorporated herein by reference.

### TECHNICAL FIELD

The invention relates to a method for monitoring a protective ground connection of an electrical feeder using a monitoring conductor, the feeder extending between a feeding point having a grounding connection and a load-side connection, comprising the method steps of generating a test current and injecting the test current at the feeding point between the monitoring conductor and the grounding connection.

Furthermore, the invention relates to a device for monitoring a protective ground connection of an electrical feeder using a monitoring conductor, the feeder extending between a feeding point having a grounding connection and a load-side connection, consisting of a test current generator for generating a test current and a coupling circuit for injecting the test current at the feeding point between the monitoring conductor and the grounding connection.

### BACKGROUND

Loop monitoring devices are known for monitoring loop resistances and protective ground connections. For example, devices of this kind are used for detecting an interruption of a protective ground in electrical installations. A monitoring device including a test current generator is coupled via a monitoring conductor or also directly to the grounded body of an electrical load on the one side and to a grounding connection on the other side. The circuit closes by way of the protective ground so that the current that can be measured in the monitoring device provides information on the continuity of the protective ground connection. An alarm is triggered if the measured current falls short of a preset response value, which is equivalent to an exceedance of a loop resistance.

One problem with this procedure relates to multiple groundings, which occur if the test current circuit closes not only via the protective ground back to the test current generator, but there also are additional parallel current paths that may lead to an inaccurate evaluation of the current flow. Furthermore, interferences occur, such as in the form of leakage currents, which superimpose themselves on the test current to be measured in the protective ground and distort the measuring result. These problems and their solution according to the invention shall be explained in the following description using the example of a shore connection for ships.

Efforts are made in the loading and unloading of ships in sea ports to provide the electrical power supply for the ships from the shore. In this way, the onboard aggregates can be shut down, saving fuel and lowering the level of pollution for the environment and especially for the residents in the surrounding area of the port.

In case of a shore connection of this kind, it must be ensured that there is a reliable protective ground connection to the ship before activating the shore feeding and while supplying power from the shore.

The known loop monitoring systems do not guarantee reliable monitoring of the protective ground connection in this specific application because these devices do not take into account parallel grounding connections, such as via the salt water and the gangways, and it consequently cannot be recognized whether the test loop actually closes only via the designated protective ground connection. An inappropriate release of the injection voltage and a protective ground that is interrupted during the injection thus has to be avoided.

Even a measurement of the current in the protective ground can lead to inaccurate evaluations because the above-described interferences superimpose themselves on the actual test current and complicate the reliable detection of the test current.

Therefore, it is the object of the present invention to develop a method and a device that ensure reliable monitoring of a protective ground connection.

### SUMMARY

This object is attained with respect to a method in conjunction with the preamble of claim 1 in that the injected test current has a characteristic temporal progression that can be clearly distinguished from currents running on the protective ground during operation, the protective ground current is measured at the feeding side and the measured protective ground current is evaluated so as to detect an interruption of the protective ground.

On the one hand, the basic idea of the invention at hand is based on the fact that the injected test current, which is generated by the active measuring method, has a progression that can be clearly distinguished from the other currents running on the protective ground. This current signature allows a clear separation of the test current portion in the measured protective ground current.

On the other hand, a current measurement takes place selectively on the feeding side in the protective ground to be monitored in conjunction with an evaluation of the measured protective ground current. In this way, it is determined whether the protective ground connection is actually the desired main grounding connection or whether parallel grounding connections only simulate a seemingly proper protective ground connection.

In another advantageous embodiment, the characteristic temporal progression of the test current is formed by a rectangular pulse train.

The temporal progression of the rectangular pulse train is significantly different from the currents running on the protective ground during operation in its shape and also in its basic frequency if the pulse width and the pulse interval are selected appropriately, and thus it allows an accurate determination of the test current portion.

Preferably, the test current portion is determined in the measured protective ground current.

In this further method step, the test current portion contained in the measured protective ground current is extracted. This detection can take place by way of suitable analog filter circuits or according to an A/D conversion of the current value by means of filter algorithms on the digital level. Since the test current has a progression that can be clearly distinguished from the other currents running on the protective ground, a reliable detection of the test current portion is possible.

The size of the determined test current portion provides information on the presence of a proper protective ground connection.

In another embodiment, the measured protective ground current is synchronized with the temporal progression of the injected test current.

Synchronizing the measured protective ground current to the test current generated by the test current generator facilitates the detection of the test current portion contained in the measured protective ground current.

Advantageously, an alarm is triggered if the determined test current portion falls short of an adjustable test current response value.

If it is discovered during the evaluation of the measured protective ground current that the determined test current portion is lower than a test current response value, i.e. lower than a predefinable trigger threshold, this indicates an interruption of the protective ground, and an alarm is triggered.

In an advantageous manner, the afore-described method is applied in conjunction with a monitoring of the protective ground in a shore connection for ships.

A reliable protective ground connection of the electrical feeder in shore feeding gains increasing importance in particular in the course of a worldwide standardization of the shore connection of ships.

However, the present invention is not limited to this specific application. Other advantageous applications can be found in all cases in which parallel multiple groundings may lead to an inaccurate interpretation of the current flow on a grounding connection and in which interference currents distort the measuring result on the protective ground itself.

With regard to a device, the object is attained in connection with the preamble of claim 7 in that the monitoring device has a connection device for connecting at least one measuring current transformer and an evaluating device for detecting an interruption of the protective ground based on a current measured with the measuring current transformer.

Since the claimed monitoring device represents a realization of the above-claimed method for monitoring a protective ground connection, the advantageous effects cited for the method equally apply to the monitoring device according to the invention.

In particular, the monitoring device has a connection device for connecting at least one measuring current transformer. This design allows registering the current directly on the protective ground so as to be able to extract a test current portion by using the clearly distinguishable current signature of the test current.

In an evaluating device, information can be gained on the electrical state of the protective ground connection on the basis of the protective ground current registered by the measuring current transformer and of the test current portion extracted therefrom.

To separate the test current portion from the interference currents present on the protective ground, the evaluating device can comprise a filter unit. Said filter unit can be realized as an analog filter circuit or as a digital filter in conjunction with an A/D conversion of the registered protective ground current.

Furthermore, the monitoring device can comprise a decision unit for detecting whether the determined test current portion falls short of an adjustable test current response value and for triggering an alarm. In the decision unit, it is defined at which point a protective ground connection is considered to be interrupted or defective and whether an alarm is to be triggered accordingly. A test current response value is used as a decision criterion for triggering the alarm when the response value is undercut.

Furthermore, the monitoring device comprises a synchronization device for synchronizing the measured protective ground current with the temporal progression of the injected test current.

The synchronization device temporally correlates the measured protective ground current and the injected test current so that the test current portion in the protective ground current subject to interferences can be reliably detected.

### BRIEF DESCRIPTION OF THE DRAWING

Other advantageous embodiment features arise from the following description and from the drawing, which illustrates a preferred embodiment of the invention with the aid of an example.

The FIGURE shows a monitoring device according to the invention in conjunction with a shore connection for ships.

### DETAILED DESCRIPTION

In a schematic illustration, the FIGURE shows an application of the method according to the invention including an embodiment of the monitoring device 2 implementing the method using the example of a shore connection for ships 4.

The ship 4 is connected to a feeding point 3 via a load-side connection 5 and an electrical feeder 6 to the main power supply. The load-side connection 5 further comprises a monitoring conductor 8 and a protective ground 10 (protective ground connection). The feeding point 3 is provided with a grounding connection 12.

The monitoring device 2, which is arranged at the feeding point 3, consists of a test current generator 14 for generating a test current 17, a coupling circuit 16 for injecting the test current 17 into the monitoring conductor 8, a connection device 18 for connecting a measuring current transformer 20 for current measurement on the protective ground 10, an evaluating device 22 for evaluating the registered protective ground current 24 and a synchronization device 26 for synchronizing the measured protective ground current 24 with the temporal progression of the injected test current 17.

In the illustrated exemplary application of the shore connection of ships, the test current 17 that is injected into the monitoring conductor 8 at the feeding point 3 can take several undefined paths back to the test current generator 14. For example, the test current circuit can close by way of the electrically conductive salt water 30 or via a gangway 32. If the test current was measured only centrally in the monitoring device 2, a current flow would be measured because of the current paths running parallel to the protective ground 10 via the salt water 30 and the gangway 32, although the protective ground 10 might be interrupted. To avoid this false interpretation, the protective ground current 24 is specifically measured according to the invention at the injection side by means of a measuring current transformer 20.

Since the protective ground current 24, too, is superimposed by interferences, which primarily originate from leakage currents flowing during operation, a pure 50/60 Hz alternating current, for example, would be difficult to extract as a test current 17 from the registered protective ground current 24. Hence, according to the invention, the test current 17 has a characteristic temporal progression that makes it clearly distinguishable from currents running on the protective ground 10 during operation.

Owing to this current signature, the test current portion can then be filtered out more easily and be subsequently evaluated in the evaluating device 22.

To further facilitate the evaluation, the monitoring device has a synchronization device 26 that synchronizes the measured protective ground current 24 with the injected test current 17.

1. A method for monitoring a protective ground (10) of an electrical feeder (6) using a monitoring conductor (8), the feeder (6) extending between a feeding point (3) having a grounding connection (12) and a load-side connection (5), comprising the method steps of:
generating a test current (17),
injecting the test current (17) at the feeding point (3) between the monitoring conductor (8) and the grounding connection (12), characterized in that
the injected test current (17) has a characteristic temporal progression that can be clearly distinguished from currents running on the protective ground (10) during operation,
a protective ground current (24) is measured at the feeding side, and
the measured protective ground current (24) is evaluated so as to detect an interruption of the protective ground.

2. The method according to claim 1,
characterized in that
the characteristic temporal progression of the test current (17) is formed by a rectangular pulse train.

3. The method according to claim 1,
characterized in that
a test current portion in the measured protective ground current (24) is determined.

4. The method according to claim 1,
characterized in that
the measured protective ground current (24) is synchronized with the temporal progression of the injected test current (17).

5. The method according to claim 3,
characterized in that
an alarm is triggered if the determined test current portion falls short of an adjustable test current response value.

6. The method according to claim 1,
characterized by
being implemented in connection with the monitoring of the protective ground in a shore connection for ships (4).

7. A device for monitoring a protective ground connection (10) of an electrical feeder (6) using a monitoring conductor (8), the feeder (6) extending between a feeding point (3) having a grounding connection (12) and a load-side connection (5), consisting of a test current generator (14) for generating a test current (17) and a coupling circuit (16) for injecting the test current (17) at the feeding point (3) between the monitoring conductor (8) and the grounding connection (12),
characterized by
a connection device (18) for connecting at least one measuring current transformer (20) and by an evaluating device (22) for detecting an interruption of the protective ground on the basis of a current (24) measured with the measuring current transformer (20).

8. The monitoring device according to claim 7,
characterized by
a synchronization device (26) for synchronizing the measured protective ground current (24) with the temporal progression of the injected test current (17).
